(19) United States
(12) Patent Application Publication
(10) Pub. No.: US 2025/0079373 A1
(43) Pub. Date: Mar. 6, 2025

(54) SEMICONDUCTOR PACKAGE

(71) Applicant: Samsung Electronics Co., Ltd., Suwon-si (KR)

(72) Inventor: Chaein Moon, Suwon-si (KR)

(21) Appl. No.: 18/740,596

(22) Filed: Jun. 12, 2024

(30) Foreign Application Priority Data
Sep. 4, 2023 (KR) 10-2023-0116674

(51) Int. Cl. H01L 23/00; H01L 23/31; H01L 23/498

(52) U.S. Cl. CPC H01L 24/14; H01L 24/05; H01L 24/13; H01L 23/31; H01L 23/49816; H01L 24/32; H01L 24/73; H01L 2224/06164; H01L 2224/13111; H01L 2224/13113; H01L 2224/13116; H01L 2224/13123; H01L 2224/13124; H01L 2224/13139; H01L 2224/13147; H01L 2224/13149; H01L 2224/13155; H01L 2224/13157; H01L 2224/1316; H01L 2224/13171; H01L 2224/13179; H01L 2224/13184; H01L 2224/1403; H01L 2224/14505; H01L 2224/14517; H01L 2224/32225; H01L 2224/73204; H01L 2924/01005; H01L 2924/01014; H01L 2924/01038; H01L 2924/01039; H01L 2924/01056; H01L 2924/0106; H01L 2924/01062

(57) ABSTRACT

A semiconductor package includes a substrate including an insulating layer and a plurality of first pads on the insulating layer; a semiconductor chip including a plurality of second pads electrically connected to at least a portion of the plurality of first pads, the plurality of second pads overlapping the at least a portion of the plurality of first pads in a first direction; and a plurality of bumps on one surface of the substrate or one surface of the semiconductor chip, each of which has at least a portion having a melting point lower than a melting point of each of the plurality of first pads and a melting point of each of the plurality of second pads, wherein the plurality of bumps include a plurality of first bumps electrically connected to at least a portion of the plurality of first pads or at least a portion of the plurality of second pads, and at least one second bump having a permeability higher than a permeability of each of the plurality of first bumps.

### CROSS-REFERENCE TO RELATED APPLICATION

This application claims benefit of priority under 35 U.S.C. § 119 to Korean Patent Application No. 10-2023-0116674, filed Sep. 4, 2023, in the Korean Intellectual Property Office, the disclosure of which is incorporated herein by reference in its entirety.

### BACKGROUND

The present inventive concept relates to a semiconductor package.

A semiconductor chip may be mounted on a substrate through various types of connection bumps. The semiconductor chip may receive power from the substrate or transmit a signal to the substrate through a plurality of bumps. In particular, as the semiconductor chip has higher performance and a higher degree of integration, the plurality of bumps connected to the semiconductor chip may be arranged to have a finer pitch.

### SUMMARY

An aspect of the present inventive concept is to provide a semiconductor package that may efficiently improve bonding reliability of a substrate and/or a semiconductor chip in a vertical direction.

According to an aspect of the present inventive concept, a semiconductor package includes a substrate including an insulating layer and a plurality of first pads on the insulating layer; a semiconductor chip including a plurality of second pads electrically connected to at least a portion of the plurality of first pads, the plurality of second pads overlapping the at least a portion of the plurality of first pads in a first direction; and a plurality of bumps on one surface of the substrate or one surface of the semiconductor chip, each of which has at least a portion having a melting point lower than a melting point of each of the plurality of first pads and a melting point of each of the plurality of second pads, wherein the plurality of bumps include a plurality of first bumps electrically connected to at least a portion of the plurality of first pads or at least a portion of the plurality of second pads, and at least one second bump having a permeability higher than a permeability of each of the plurality of first bumps.

According to an aspect of the present inventive concept, a semiconductor package includes a substrate including an insulating layer and a plurality of first pads on the insulating layer; a semiconductor chip including a plurality of second pads electrically connected to at least a portion of the plurality of first pads, the plurality of second pads overlapping the at least a portion of the plurality of first pads in a first direction; and a plurality of bumps on one surface of the substrate or one surface of the semiconductor chip, each of which has at least a portion having a melting point lower than a melting point of each of the plurality of first pads and a melting point of each of the plurality of second pads, wherein at least one bump, among the plurality of bumps, includes a first magnetic core; a second magnetic core configured to apply magnetic force to the first magnetic core; and a solder contacting the first and second magnetic cores, at least partially surrounding the first and second magnetic cores, and having a melting point lower than a melting point of the first magnetic core and a melting point of the second magnetic core.

According to an aspect of the present inventive concept, a semiconductor package includes a substrate including an insulating layer and a plurality of first pads on the insulating layer; a semiconductor chip including a plurality of second pads electrically connected to at least a portion of the plurality of first pads, the plurality of second pads overlapping the at least a portion of the plurality of first pads in a first direction; and a plurality of bumps on one surface of the substrate or one surface of the semiconductor chip, each of which has at least a portion having a melting point lower than a melting point of each of the plurality of first pads and a melting point of each of the plurality of second pads, wherein the plurality of bumps include a plurality of first bumps connected between at least a portion of the plurality of first pads and at least a portion of the plurality of second pads; and a plurality of second bumps including a dummy bump that is not connected to the plurality of first pads or that is not connected to the plurality of second pads, wherein the plurality of second bumps includes a ferromagnetic material or a permanent magnetic material, respectively.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a cross-sectional view illustrating an X-Z cross-section of a semiconductor package according to an embodiment.

FIG. 2A is an enlarged cross-sectional view of portion ‘A’ of the semiconductor package of FIG. 1.

FIG. 2B is a plan view illustrating an X-Y cross-section of the semiconductor package of FIG. 2A.

FIGS. 3A to 3C are enlarged cross-sectional views of a semiconductor package according to an embodiment.

FIGS. 4A to 4D are enlarged cross-sectional views of a semiconductor package according to an embodiment.

FIGS. 5A to 5G are plan views illustrating an arrangement of a plurality of bumps and a plurality of pads of a semiconductor package according to an embodiment, respectively.

FIGS. 6A and 6B are cross-sectional views illustrating a semiconductor package according to an embodiment.

FIGS. 7A to 7C are cross-sectional views illustrating a method of manufacturing a semiconductor package according to an embodiment.

### DETAILED DESCRIPTION

Detailed description of the present inventive concept to be described below refers to the accompanying drawings which, by way of example, illustrate specific embodiments in which the present inventive concept may be practiced. These embodiments are described in sufficient detail to enable one skilled in the art to practice the present inventive concept. It should be understood that the various embodiments of the present inventive concept are different from each other but are not necessarily mutually exclusive. For example, one embodiment of specific shapes, structures, and characteristics described herein may be implemented in another embodiment without departing from the spirit and scope of the present inventive concept. Additionally, it should be understood that the position or arrangement of individual components within each disclosed embodiment may be changed without departing from the spirit and scope of the present inventive concept. Accordingly, the detailed description set forth below is not intended to be taken in a limiting sense, and the scope of the present inventive concept is limited only by the appended claims, with all equivalents as claimed by those claims. Like reference numbers in the drawings indicate the same or similar functions throughout the various aspects. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

Hereinafter, embodiments of the present inventive concept will be described in detail with reference to the accompanying drawings such that those skilled in the art may readily practice the present inventive concept.

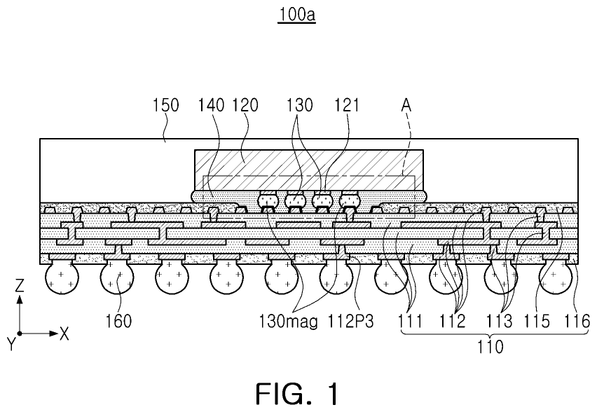

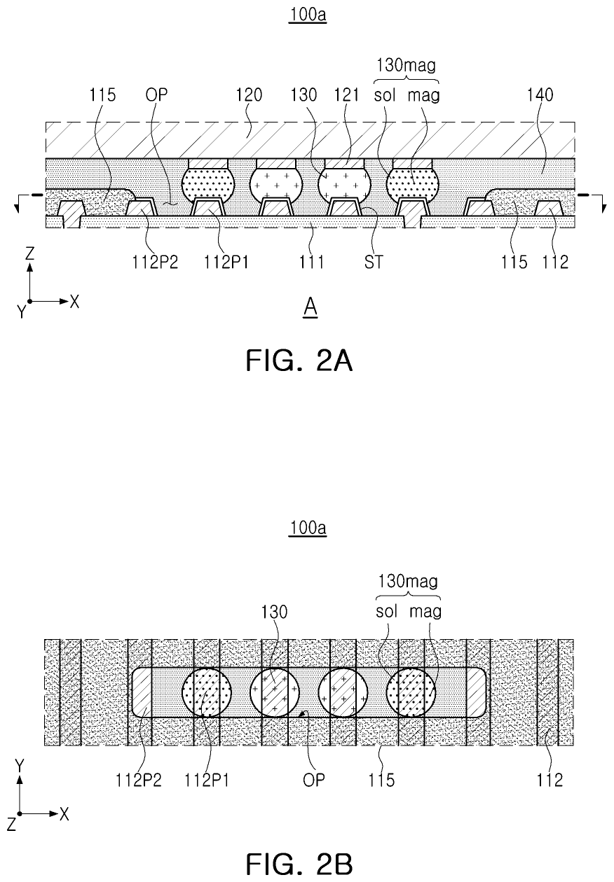

Referring to FIGS. 1 to 2B, a semiconductor package 100a according to an embodiment may include a substrate 110, a semiconductor chip 120, and a plurality of bumps, and the plurality of bumps may include a plurality of first bumps 130, and at least one second bump 130mag.

The substrate 110 may be a support substrate on which the semiconductor chip 120 is mounted, and may be a package substrate for interconnecting pads of the semiconductor chip 120. The package substrate may include a printed circuit board (PCB), a ceramic substrate, a glass substrate, a tape interconnection substrate, or the like. The substrate 110 may include insulating layers 111, interconnection layers 112, interconnection vias 113, a first solder mask layer 115, and a second solder mask layer 116. In some embodiments, the number of insulating layers 111 and interconnection layers 112, forming the substrate 110, may be changed. In some embodiments, the substrate 110 may be an interposer substrate, for example, an organic interposer. In some embodiments, the substrate 110 may be a module substrate, and, in this case, the semiconductor chip 120 may be a semiconductor structure, such as a semiconductor package.

The insulating layers 111 may include an insulating material, and may include, for example, a thermosetting resin, such as an epoxy resin or a thermoplastic resin, such as polyimide. For example, the insulating layers 111 may include a photosensitive insulating material, such as a photoimagable dielectric (PID) resin. In other embodiments, the insulating layers 111 may include a resin mixed with an inorganic filler, for example, an Ajinomoto build-up film (ABF). In other embodiments, the insulating layers 111 may include a prepreg, e.g., a flame retardant (FR-4), or bismaleimide triazine (BT). The insulating layers 111 may contain the same or different materials, and a boundary therebetween may not be distinguished, depending on materials, processes, or the like forming each layer. That is, the insulating layers 111 may be embodied as a unitary or monolithic structure.

The interconnection layers 112 and the interconnection vias 113 may form an electrical path. The interconnection layers 112 and the interconnection vias 113 may interconnect the semiconductor chip 120 to a region outside the semiconductor chip 120, for example, to a fan-out region that does not overlap the semiconductor chip 120 in a Z-direction. Therefore, the semiconductor package 100a of the present embodiment may be referred to as a fan-out semiconductor package. A form of the semiconductor package is not limited thereto, and in some embodiments, the semiconductor package 100a may form a fan-in semiconductor package. The interconnection layers 112 and the interconnection vias 113 may include a ground pattern, a power pattern, and a signal pattern. The interconnection layers 112 may be arranged in a linear shape on an X-Y plane, and the interconnection vias 113 may have a cylindrical shape having a side surface inclined, such that a width is reduced in the X-Y plane in an upward direction or a downward direction along the Z direction axis. The interconnection vias 113 are illustrated as filled via structures of which interiors are completely filled with a conductive material, but embodiments of the interconnection vias 113 are not limited thereto. For example, the interconnection vias 113 may have a conformal via shape in which a metal material is formed along an internal wall of a via hole.

The interconnection layers 112 and the interconnection vias 113 may include a conductive material, and may include, for example, copper (Cu), aluminum (Al), silver (Ag), tin (Sn), gold (Au), nickel (Ni), lead (Pb), titanium (Ti), or alloys thereof. Depending on a width of an interconnection or an interval between interconnections (e.g., 10 μm to 100 μm) in the interconnection layers 112, the interconnection of the interconnection layers 112 may be implemented as a redistribution line.

The interconnection layers 112 may include a plurality of first pads 112P1, 112P2, and 113P3 exposed through the first and second solder mask layers 115 and 116. A portion of uppermost interconnection layers 112 may form a plurality of first pads 112P1 and 112P2. A portion of lowermost interconnection layers 112 may form a plurality of first pads 112P3. The plurality of first pads 112P1 and 112P2 may be disposed on an uppermost insulating layer among the insulating layers 111, and the plurality of first pads 112P3 may be disposed on a lowermost insulating layer among the insulating layers 111.

FIGS. 1 and 2A illustrate a substrate 110, which is a protruded trace substrate (PTS) in which the plurality of first pads 112P1, 112P2, and 113P3 protrude upward and downward along the Z direction axis from upper and lower surfaces of the insulating layers 111. The substrate 110 may be an embedded trace substrate (ETS). The ETS may have a structure in which the uppermost insulating layer of the insulating layers 111 is recessed upward and downward along the Z direction axis in regions overlapping the plurality of first pads 112P1 and 112P2, and the plurality of first pads 112P1 and 112P2 may be in direct contact with the uppermost insulating layer of the insulating layers 111 in recessed spaces of the uppermost insulating layer among the insulating layers 111.

Each of the plurality of first pads 112P1 and 112P2 may include a surface treatment layer ST disposed on a surface exposed from the first solder mask layer 115. Depending on a design, the surface treatment layer ST may be omitted. The surface treatment layer ST may be disposed on entire surfaces of the plurality of first pads 112P1, and may be disposed on a portion of surfaces of the plurality of first pads 112P2 exposed through an opening OP. The surface treatment layer ST may include, for example, gold (Au), silver (Ag), nickel (Ni), and/or palladium (Pd). Although not illustrated, the plurality of first pads 113P3 may further include a surface treatment layer disposed on a surface exposed from the second solder mask layer 116.

The plurality of first pads 112P1 may be pads for mounting the semiconductor chip 120. The plurality of first pads 112P1 may be pads entirely exposed by the first solder mask layer 115, and may be connected to the plurality of first bumps 130. Depending on a design, the first pads 112P2 among the plurality of first pads 112P1 and 112P2 may be omitted. The plurality of first pads 112P2 may be pads at least partially exposed by the first solder mask layer 115, and may not be connected to the plurality of first bumps 130. In the plurality of first pads 112P2, upper surfaces and side surfaces exposed from the first solder mask layer 115 may be at least partially covered with a non-conductive film layer 140, and may be in contact with the non-conductive film layer 140. The plurality of first pads 112P2 may be disposed one on both sides of a group of the plurality of first pads 112P1 in at least one direction, for example, an X-direction. The plurality of first pads 112P3 may be pads connected to package bumps 160.

The first and second solder mask layers 115 and 116 may be solder resist layers that may protect the interconnection layer 112 from external physical and chemical damage. The first and second solder mask layers 115 and 116 may include an insulating material, for example, a prepreg, an ABF, an FR-4, BT, and/or a photo solder resist (PSR). The first solder mask layer 115 may form an upper surface of the substrate 110, and may have the opening OP exposing at least a portion of the interconnection layer 112, for example, the plurality of first pads 112P1 and 112P2. The second solder mask layer 116 may have a plurality of openings exposing at least a portion of the interconnection layer 112, for example, the plurality of first pads 112P3.

The semiconductor chip 120 may be disposed on the substrate 110 to overlap in a vertical direction, i.e., Z direction, and may include a plurality of second pads 121 on a lower surface thereof. The semiconductor chip 120 may be mounted on the upper surface of the substrate 110 using a flip-chip bonding method. The semiconductor chip 120 may be located below the plurality of second pads 121, and may include a device layer or an active layer on which an integrated circuit (IC) is disposed. The semiconductor chip 120 may include a logic semiconductor chip and/or a memory semiconductor chip. The logic semiconductor chip may be a microprocessor, and may be, for example, a central processing unit (CPU), a graphics processing unit (GPU), a field programmable gate array (FPGA), an application processor (AP), a digital signal processor, a cryptographic processor, a controller, and/or an application specific integrated circuit (ASIC). The memory semiconductor chip may be a volatile memory, such as a dynamic random access memory (DRAM), a static random access memory (SRAM), or the like, or a non-volatile memory, such as a flash memory or the like.

A body portion of the semiconductor chip 120 may include silicon (Si), germanium (Ge), gallium arsenide (GaAs), or the like, and the plurality of second pads 121 may include a conductive material, such as tungsten (W), aluminum (Al), copper (Cu), or the like. The plurality of second pads 121 may be pads of a bare chip, for example, pads of aluminum (Al), but depending on embodiments, pads of a packaged chip, for example, pads of copper (Cu).

The plurality of second pads 121 may be electrically connected to the plurality of first pads 112P1 through the plurality of first bumps 130. Being electrically connected may mean providing at least a portion of a path through which a signal is transmitted. In some embodiments, the plurality of second pads 121 may be disposed in the body portion of the semiconductor chip 120, such that a lower surface thereof forms a lower surface of the semiconductor chip 120. In some embodiments, a passivation layer exposing the plurality of second pads 121 may be further disposed on the lower surface of the semiconductor chip 120. The passivation layer may include a silicon oxide film and/or a silicon nitride film.

The plurality of first and second bumps 130 and 130mag may be disposed on one surface (upper surface and/or lower surface) of the substrate 110 or one surface (upper surface and/or lower surface) of the semiconductor chip 120, and at least a portion thereof may have a melting point lower than a melting point of each of the plurality of first and second pads 112P1 and 121. The plurality of first bumps 130 may physically and electrically connect at least a portion of the plurality of second pads 121 of the semiconductor chip 120 to at least a portion of the plurality of first pads 112P1 of the substrate 110. The plurality of first bumps 130 may not be connected to the first pads 112P2. The plurality of first and second bumps 130 and 130mag may have a ball shape or a pillar shape. The plurality of first and second bumps 130 and 130mag may at least partially cover upper portions of upper surfaces and side surfaces of the plurality of first pads 112P1.

The plurality of first and second bumps 130 and 130mag may include a conductive material having a low melting point, such as lead (Pb), bismuth (Bi), tin (Sn), and/or a tin alloy (Sn—Ag—Cu). At a temperature higher than the melting point, the plurality of first and second bumps 130 and 130mag may be in a fluid state by a reflow process or a thermal compression bonding (TCB) process. Thereafter, as the temperature decreases, the plurality of first bumps 130 will be connected and fixed between at least a portion of the plurality of first pads 112P1 and at least a portion of the plurality of second pads 121. Therefore, the semiconductor chip 120 may be mounted on the substrate 110.

During the reflow process or the thermal compression bonding (TCB) process, the horizontal position difference, i.e., position difference in the X direction, between at least a portion of the plurality of first pads 112P1 and at least a portion of the plurality of second pads 121 (which may be expressed as an offset) may be a cause of incorrect electrical connection between at least a portion of the plurality of first pads 112P1 and at least a portion of the plurality of second pads 121. Therefore, the horizontal position difference (e.g., offset) may be lowered to reduce possibility of incorrect connection between at least a portion of the plurality of first pads 112P1 and at least a portion of the plurality of second pads 121.

The at least one second bump 130mag may have permeability higher than permeability of each of the plurality of first bumps 130. Therefore, the at least one second bump 130mag may be magnetized, and thus may become a source of magnetic force. When a horizontal position difference (e.g., offset) occurs between at least a portion of the plurality of first pads 112P1 and at least a portion of the plurality of second pads 121, since magnetic force may include not only a vertical vector component but also a horizontal vector component, the horizontal position difference (e.g., offset) may be changed due to the horizontal vector component.

The at least one second bump 130mag may coexist with the plurality of first bumps 130. Because the permeability of each of the plurality of first bumps 130 may be lower than the permeability of the at least one second bump 130mag, the plurality of first bumps 130 may not be substantially affected by magnetic force of the at least one second bump 130mag. Therefore, the magnetic force of the at least one second bump 130mag may not further increase the horizontal position difference (e.g., offset), and the magnetic force may reliably reduce the horizontal position difference (e.g., offset) due to the horizontal vector component. For example, incorrect connection between at least a portion of the first pads 112P1 and at least a portion of the second pads 121 may be stably reduced or prevented. Additionally, due to the stable reduction or prevention of incorrect connections, sizes and interval of the plurality of first and second pads 112P1 and 121 may be stably reduced. For example, the semiconductor package 100a may be advantageous in miniaturization while improving reliability.

For example, the at least one second bump 130mag may be connected between a different portion of the plurality of first pads 112P1 and a different portion of the plurality of second pads 121. Because not only the plurality of first bumps 130 but also at least a portion of the at least one second bump 130mag may have a melting point lower than a melting point of each of the plurality of first and second pads 112P1 and 121, the plurality of first bumps 130 and the at least one second bump 130mag may provide electrical connection paths between the substrate 110 and the semiconductor chip 120 in parallel, and may be formed simultaneously.

The at least one second bump 130mag may include a solder (sol) and a magnetic material (mag). The solder (sol) may have a melting point lower than a melting point of each of the plurality of first and second pads 112P1 and 121, and the plurality of first bumps 130 may be formed of the solder. The magnetic material (mag) may include a magnetic material having a magnetic permeability higher than a magnetic permeability of a material included in each of the plurality of first and second pads 112P1 and 121. For example, the magnetic material (mag) may include a ferromagnetic material. The ferromagnetic material may include a ferro-magnetic material, a ferri-magnetic material, and/or an anti-ferromagnetic material, and may form a magnetic force as the ferromagnetic material is magnetized. For example, the ferromagnetic material may include ferrite, iron (Fe), nickel (Ni), cobalt (Co), tungsten (W), molybdenum (Mo), or alloys thereof. For example, the ferromagnetic material may be amorphous or crystalline, and may include one or more of an Fe-Si-based alloy, an Fe-Si-Al-based alloy, an Fe-Ni-based alloy, an Fe-Ni-Mo-based alloy, an Fe-Ni-Mo-Cu-based alloy, an Fe-Co-based alloy, an Fe-Ni-Co-based alloy, an Fe-Cr-based alloy, an Fe-Cr-Si-based alloy, an Fe-Si-Cu-Nb-based alloy, an Fe-Ni-Cr-based alloy, an Fe-Cr-Al-based alloy, or an Fe-Si-B-Cr-based alloy. The ferrite may be, for example, at least one of spinel-type ferrite such as Mg-Zn-based ferrite, Mn-Zn-based ferrite, Mn-Mg-based ferrite, Cu-Zn-based ferrite, Mg-Mn-Sr-based ferrite, Ni-Zn-based ferrite, or the like, hexagon-type ferrite such as Ba-Zn-based ferrite, Ba-Mg-based ferrite, Ba-Ni-based ferrite, Ba-Co-based ferrite, Ba-Ni-Co-based ferrite, or the like, garnet-type ferrite such as Y-based ferrite or the like, and/or Li-based ferrite.

In other embodiments, the magnetic material mag of the at least one second bump 130mag may include a permanent magnet material. The permanent magnet material may be a material that may preserve a strong magnetization state for a long time, and may thus form a magnetic force without a separate magnetization process. For example, the permanent magnet material may be a mixture of the ferromagnetic material (e.g., ferrite) and an additional material (e.g., neodymium (Nd), samarium (Sm), or the like).

Referring to FIGS. 1 to 2B, a semiconductor package 100a according to an embodiment may further include a non-conductive film layer 140, an encapsulant 150, and/or package bumps 160.

The non-conductive film layer 140 may be disposed between the semiconductor chip 120 and the substrate 110 to at least partially surround the plurality of first bumps 130 and the at least one second bump 130mag in a plan view. The non-conductive film layer 140 may also be referred to as an underfill layer. The non-conductive film layer 140 may include a non-conductive polymer, and may include, for example, a non-conductive paste (NCP). The non-conductive film layer 140 may be formed on the lower surface of the semiconductor chip 120 or the upper surface of the substrate 110 during a reflow process or a TCB process, and may then at least partially fill a space between the semiconductor chip 120 and the substrate 110. Therefore, the non-conductive film layer 140 may have a shape protruding from end portions of the semiconductor chip 120 in an outward direction. A length in which the non-conductive film layer 140 protrudes horizontally from side surfaces of the semiconductor chip 120 may be greater at a center of the non-conductive film layer 140 in a thickness direction than on upper and lower surfaces of the non-conductive film layer 140.

The encapsulant 150 may seal and protect the semiconductor chip 120. The encapsulant 150 may be disposed to at least partially cover the side surfaces and the upper surface of the semiconductor chip 120, but embodiments are not limited thereto. The encapsulant 150 may include, but is not limited to, a molding material, such as an epoxy molding compound (EMC). For example, the encapsulant 150 may include an insulating material, and may include, for example, a thermosetting resin, such as an epoxy resin, a thermoplastic resin, such as polyimide, an inorganic filler, and/or a prepreg containing glass fiber, ABF, or FR-4, BT, or PID.

The package bumps 160 may be disposed in openings of the second solder mask layer 116 on the lower surface of the substrate 110. The package bumps 160 may physically and/or electrically connect the semiconductor package 100a to an external device, such as a main board or the like. The package bumps 160 may have a size and a diameter, greater than those of each of the plurality of first bumps 130. The package bumps 160 may include a low melting point metal, for example, tin (Sn), an alloy containing tin (Sn) (Sn—Ag—Cu), or the like, but is not limited thereto. The package bumps 160 may have a land shape, a ball shape, or a pin shape, and may be formed as a single layer or multiple layers. For example, the package bumps 160 may be solder balls.

Referring to FIG. 2A, at least one second bump 130mag of a semiconductor package 100a according to an embodiment may include a magnetic material mag having a powder form, dispersed in a solder sol. An average diameter of the magnetic material mag may be less than 10% of an average diameter of each of the at least one second bump 130mag, but embodiments are not limited thereto.

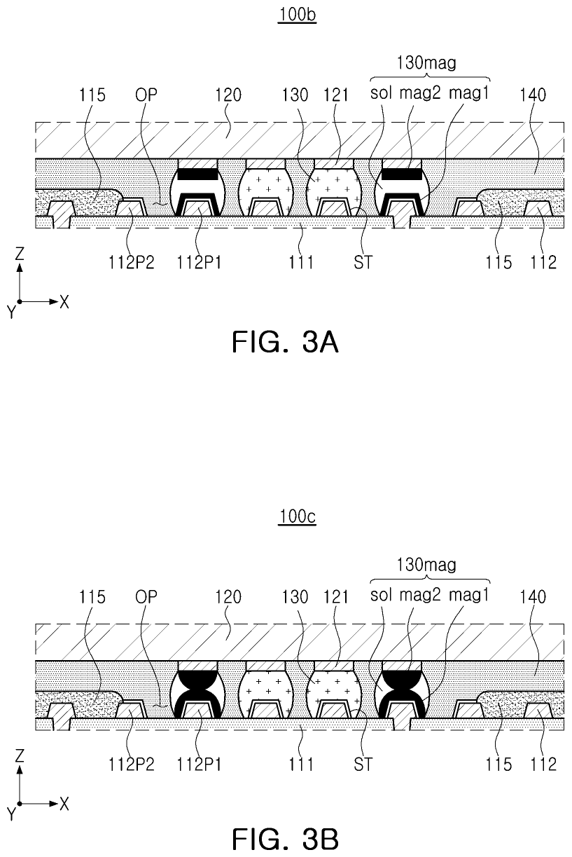

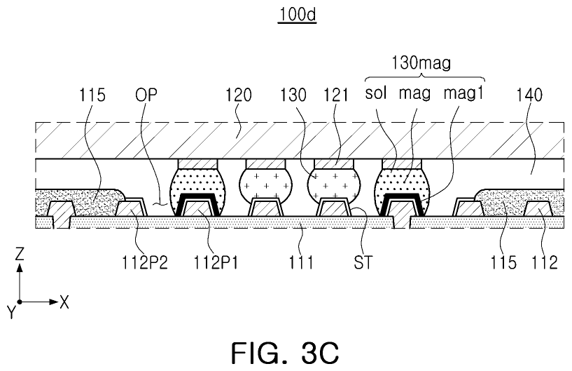

Referring to FIGS. 3A and 3B, at least one second bump 130mag of a semiconductor package (100b and 100c) according to an embodiment may include a solder (sol), a first magnetic core mag1, and a second magnetic core mag2, respectively. The first magnetic core mag1 may be in direct contact with one of a plurality of first pads 112P1, and the second magnetic core mag2 may be in direct contact with one of a plurality of second pads 121.

The first magnetic core mag1 may be configured to apply magnetic force to the second magnetic core mag2 by including a permanent magnet material or being temporarily magnetized, and the second magnetic core mag2 may be configured to apply magnetic force to the first magnetic core mag 1 by including a permanent magnet material or being temporarily magnetized. Each of the first and second magnetic cores mag1 and mag2 may be formed of a magnetic material (e.g., a ferromagnetic material and/or a permanent magnet material) having a permeability higher than permeability of each of the plurality of first and second pads 112P1 and 121. As a volume of each of the first and second magnetic cores mag1 and mag2 increases, magnetic force between the first and second magnetic cores mag1 and mag2 may increase. The volume of each of the first and second magnetic cores mag1 and mag2 may be 10% or more of a volume of each of the at least one second bump 130mag, but embodiments are not limited thereto.

For example, before a semiconductor chip 120 is disposed on a substrate 110, the first magnetic core mag1 may be disposed on at least a portion of the plurality of first pads 112P1 of the substrate 110, and the second magnetic core mag2 may be disposed on at least a portion of the plurality of second pads 121 of the semiconductor chip 120. Thereafter, when the semiconductor chip 120 is disposed on the substrate 110, the first magnetic core mag1 and the second magnetic core mag2 may be attracted to each other by magnetic force.

Because a solder (sol) is in contact with each of the first and second magnetic cores mag1 and mag2 and, as shown in FIG. 3A, at least partially surrounds the first and second magnetic cores mag1 and mag2, respectively, a vertical distance, i.e., distance along the Z-axis, between the first and second magnetic cores mag1 and mag2 may be shortened. As the vertical distance decreases, the influence of magnetic force between the first and second magnetic cores mag1 and mag2 on each other may increase. Additionally, a horizontal position, i.e., position along the X-axis, of the first magnetic core mag1 on the substrate 110 and a horizontal position of the second magnetic core mag2 on the semiconductor chip 120 may not be substantially changed. Therefore, a horizontal position difference along the X-axis (e.g., offset) between at least a portion of the first pads 112P1 and at least a portion of the second pads 121 may be efficiently offset. Additionally, even when the number of at least one second bump 130mag is relatively small compared to a plurality of first bumps 130, the horizontal position difference (e.g., offset) may be stably offset.

Referring to FIG. 3A, a first magnetic core mag1 may be formed as a layer on an upper surface of a plurality of first pads 112P1, and a second magnetic core mag2 may be formed as a layer on a lower surface of a plurality of second pads 121. Each of the first and second magnetic cores mag1 and mag2 may be implemented in a manner of applying or plating a magnetic material, but embodiments are not limited thereto.

Referring to FIG. 3B, first and second magnetic cores mag1 and mag2 may protrude from one of a plurality of first and second pads 112P1 and 121, and may be in contact with each other. For example, when a semiconductor chip 120 may be disposed on the substrate 110, vertical sizes, e.g., length along the Z-axis, of the first and second magnetic cores mag1 and mag2 may be longer by magnetic force between the first and second magnetic cores mag1 and mag2. In other embodiments, before the semiconductor chip 120 is disposed on a substrate 110, each of the first and second magnetic cores mag1 and mag2 may be formed to be thick.

Referring to FIG. 3C, at least one second bump 130mag of a semiconductor package 100d according to an embodiment may have a structure in which a magnetic material (mag) having a powder form, dispersed in a solder (sol), and a first magnetic core mag1 are mixed, respectively. In other embodiments, the at least one second bump 130mag may have a structure in which the second magnetic core mag2 of FIGS. 3A and 3B and a magnetic material (mag) having a powder form are mixed.

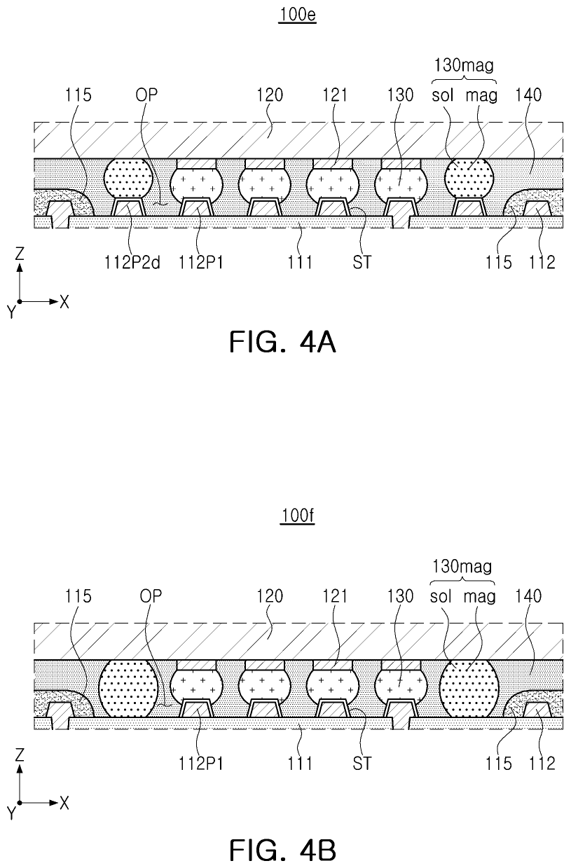

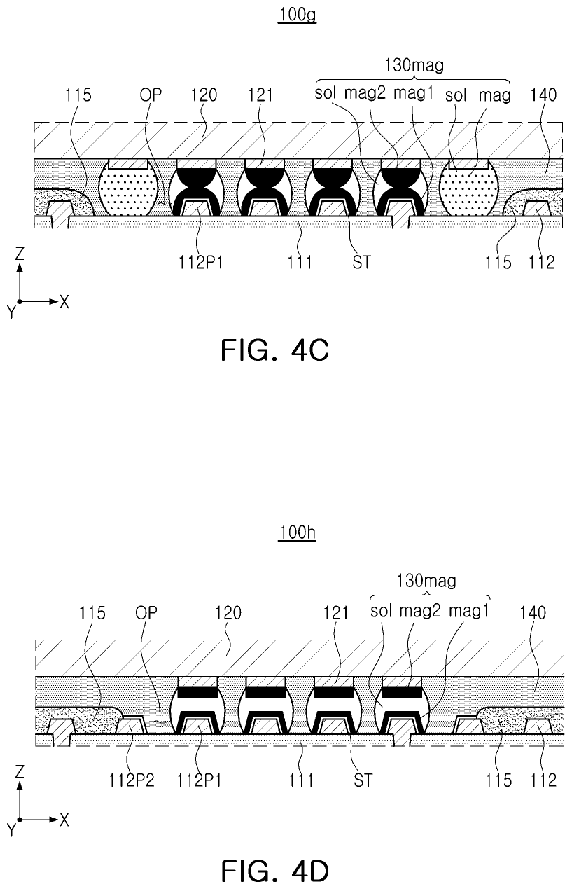

Referring to FIGS. 4A and 4B, at least one second bump 130mag of a semiconductor package (100e and 100f) according to an embodiment may include a dummy bump not connected to a plurality of first pads 121P1 or not connected to the a plurality of second pads 121. Therefore, the at least one second bump 130mag may not form an electrical connection path between a substrate 110 and a semiconductor chip 120, and may be thus designed without considering reliability of the electrical connection path (e.g., an effect according to crack occurrence, energy loss due to an increase in specific resistance, signal integrity, power integrity, or the like). Therefore, a degree of freedom in design related to permeability or magnetism of the at least one second bump 130mag may further increase, and the at least one second bump 130mag may form a magnetic force more efficiently. Additionally, even though the number of at least one second bump 130mag may be relatively small compared to a plurality of first bumps 130, the horizontal position difference (e.g., offset), e.g., position difference along the X-axis, may be stably offset. In addition, because a degree of freedom in arrangement of the at least one second bump 130mag may further increase, the at least one second bump 130mag may be advantageously disposed at a desirable position (e.g., at a position adjacent to corners of the semiconductor chip 120.

A volume of the at least one second bump (130mag) may be greater than a volume of each of the plurality of first bumps 130. Therefore, because the at least one second bump 130mag may stably at least partially fill a space added by not being connected to the plurality of first pads 121P1 or the plurality of second pads 121, imbalance in size between the at least one second bump 130mag and the plurality of first bumps 130 may be suppressed, and a warpage factor of the substrate 110 or the semiconductor chip 120 may be reduced. In other embodiments, because a horizontal size, e.g., length in the X-direction, of each of the at least one second bump 130mag may be larger than a horizontal size of each of the plurality of first bumps 130, and the at least one second bump 130mag may have a larger space accommodating a magnetic material, a magnetic force may advantageously be further strengthened.

Referring to FIGS. 4C and 4D, a semiconductor package (100g and 100h) according to an embodiment may include a plurality of second bumps 130mag, and may not include a plurality of first bumps having relatively lower permeability. Referring to FIG. 4C, a magnetic structure of the dummy bumps among a plurality of second bumps 130mag may be different from a magnetic structure of second bumps connected between a plurality of first and second pads 112P1 and 121. Referring to FIG. 4D, a plurality of second bumps 130mag may be substantially equal to each other.

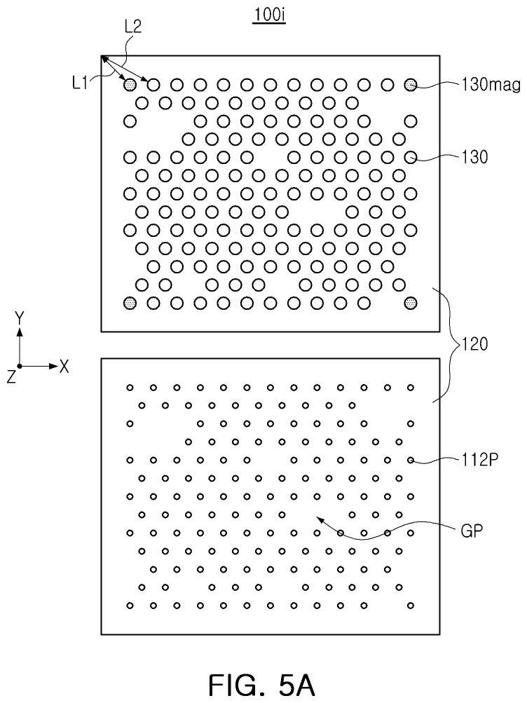

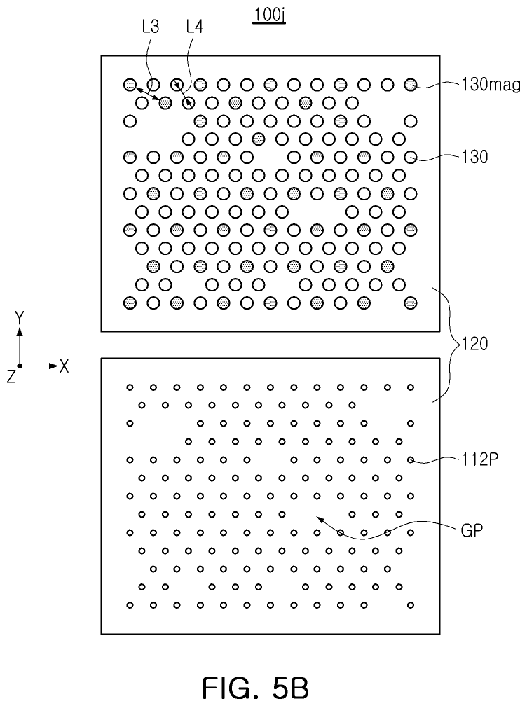

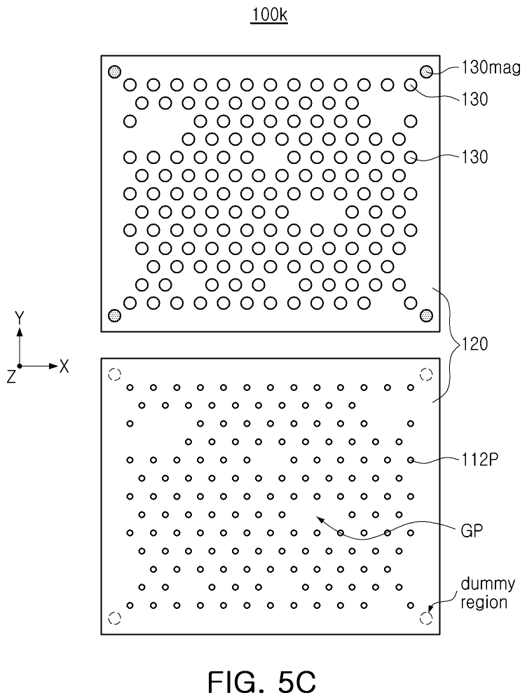

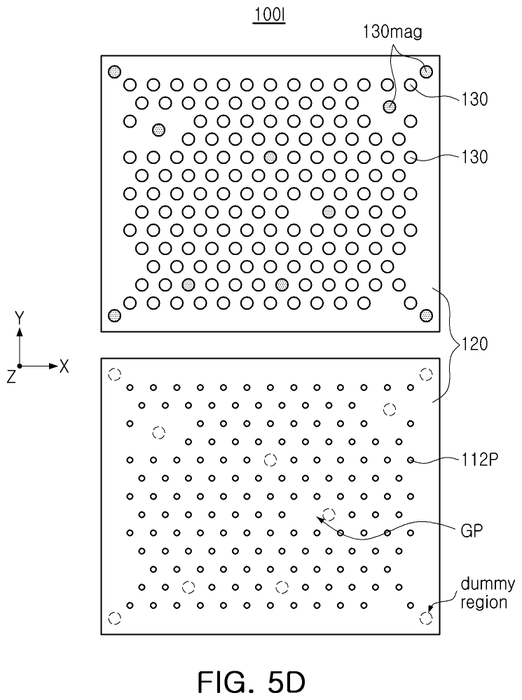

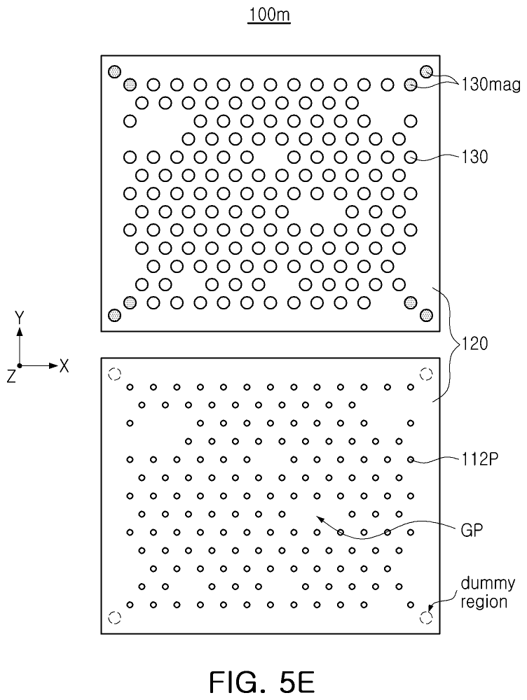

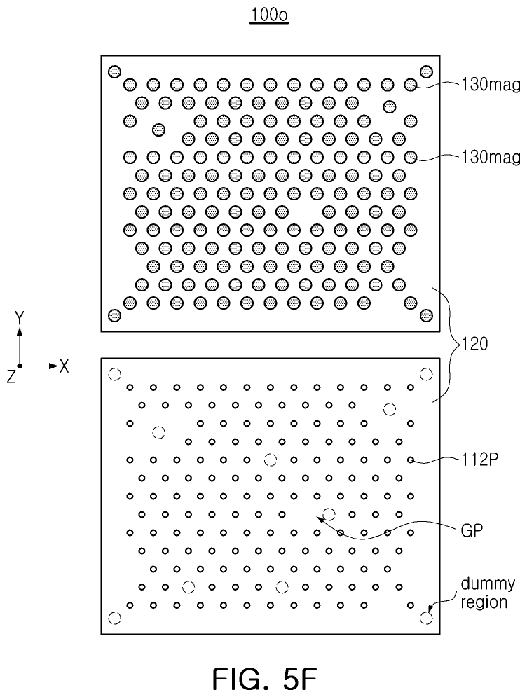

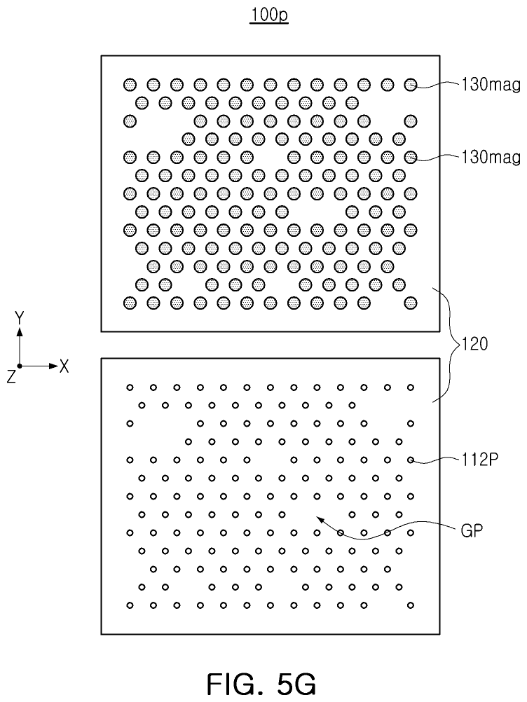

An upper portion of each of FIGS. 5A to 5G represents arrangement of a plurality of first and second bumps 130 and 130mag, and a lower portion of each of FIGS. 5A to 5G represents arrangement of a plurality of first pads 112P. Specific sizes, the number, shapes, and arrangement of the plurality of first and second bumps 130 and 130mag and the plurality of pads 112P may be changed, depending on a design.

Referring to FIGS. 5A to 5G, among a plurality of bumps of a semiconductor package (100i, 100j, 100k, 100l, 100m, 100o, and 100p) according to an embodiment, two bumps most adjacent to two corners of a semiconductor chip 120, not adjacent to each other, may be at least a portion of the plurality of second bumps 130mag. The two corners of the semiconductor chip 120, not adjacent to each other, may be an upper right corner and a lower left corner, or an upper left corner and a lower right corner of the semiconductor chip 120. In other embodiments, among the plurality of bumps, four bumps most adjacent to each corner of the semiconductor chip 120 may be at least a portion of the plurality of second bumps 130mag. Referring to FIG. 5A, a separation distance L1 between corners of the semiconductor chip 120 and second bumps 130mag adjacent to the corners of the semiconductor chip 120, among the plurality of second bumps 130mag, may be shorter than a separation distance L2 between corners of the semiconductor chip 120 and first bumps 130 most adjacent to the corners of the semiconductor chip 120, among a plurality of first bumps 130. Therefore, because a degree of freedom in position or a degree of freedom in structure in the plurality of second bumps 130mag may further increase, the plurality of second bumps 130mag may form magnetic force more efficiently.

Referring to FIG. 5B, a separation distance L3 between two second bumps most adjacent to each other, among the plurality of second bumps 130mag, may be longer than a separation distance L4 between two first bumps most adjacent to each other, among the plurality of first bumps 130. Therefore, the impact of a magnetic force of at least one second bump 130mag may be reduced or prevented from further increasing a horizontal position difference (e.g., offset) of pads, and the magnetic force may stably reduce the horizontal position difference (e.g., offset) due to a horizontal vector component of the magnetic force. Referring to FIGS. 5A to 5E, the number of at least one second bump 130mag may be less than the number of the plurality of first bumps 130.

Referring to FIGS. 5A, 5B, 5D, and 5G, the plurality of second bumps 130mag may be connected to a portion of a plurality of first pads 112P. Referring to FIG. 5C, the plurality of second bumps 130mag may not be connected to a plurality of first pads 112P, and may overlap vertically, i.e., along the Z-axis, in a dummy region. Referring to FIGS. 5E and 5F, only a portion of the plurality of second bumps 130mag may be connected to a portion of a plurality of first pads 112P, and a different portion of the plurality of second bumps 130mag may overlap vertically, i.e., along the Z-axis, in a dummy region.

Referring to FIGS. 5A to 5G, an arrangement of the plurality of first pads 112P may have a blank region GP. Referring to FIGS. 5A to 5E, an arrangement of the plurality of first bumps 130 may also have a structure not arranged in a region vertically overlapping, i.e., along the Z-axis, the blank region GP. Referring to FIGS. 5D and 5F, at least a portion of the plurality of second bumps 130mag may be disposed in a region vertically overlapping, i.e., along the Z-axis, the blank region GP. Referring to FIGS. 5F and 5G, a semiconductor package (100o and 100p) according to an embodiment may include a plurality of second bumps 130mag, and may not include a plurality of first bumps having relatively lower permeability.

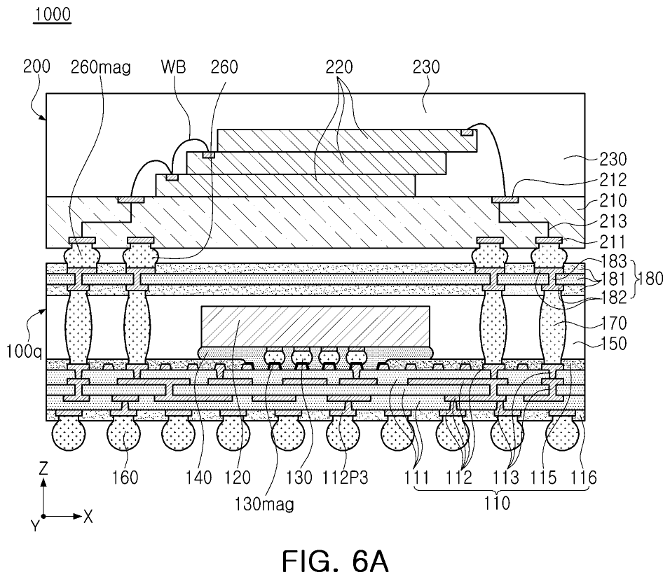

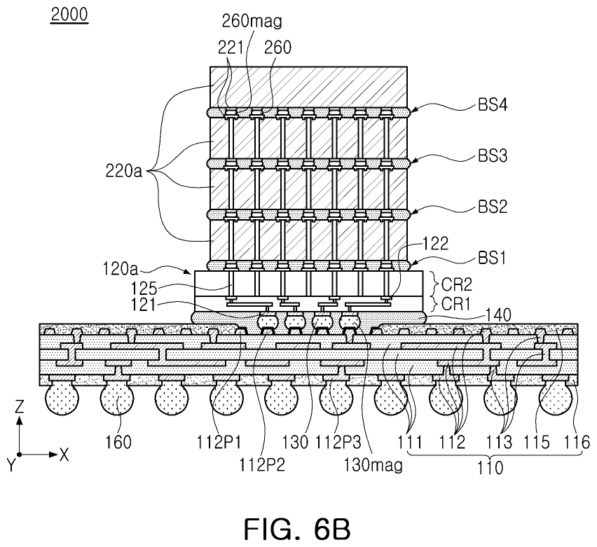

Referring to FIG. 6A, unlike the embodiment of FIG. 1, a semiconductor package 1000 may further include a second semiconductor package 200 disposed on a first semiconductor package 100q. For example, the semiconductor package 1000 may be a package-on-package (POP) type in which the second semiconductor package 200 is stacked on the first semiconductor package 100q, and may be functionally a system-in-package (SIP) type.

Compared to the semiconductor package 100a described above with reference to FIGS. 1 to 2B, the first semiconductor package 100q may further include conductive posts 170 extending into or penetrating the encapsulant 150, and a substrate 180 on the conductive posts 170.

The conductive posts 170 may be disposed between a substrate 110 and the substrate 180 to electrically connect the substrate 110 and the substrate 180. The conductive posts 170 may extend between the substrate 110 and the substrate 180 in a vertical direction, for example, the Z-direction, to provide a vertical connection path electrically connecting an interconnection layer 112 and an upper interconnection layer 182. The conductive posts 170 may include, for example, tin (Sn), indium (In), bismuth (Bi), antimony (Sb), copper (Cu), silver (Ag), zinc (Zn), lead (Pb), and/or an alloy containing these, and may have a spherical shape or a ball shape extending in the Z-direction.

The substrate 180 may be a substrate that provides an interconnection layer on an upper surface of the first semiconductor package 100q, and may be disposed between a lower package and an upper package in a POP structure. The substrate 180 may include upper insulating layers 181, upper interconnection layers 182, and interconnection vias 183. Because the upper insulating layers 181, the upper interconnection layers 182, and the interconnection vias 183 may have characteristics, identical to or similar to characteristics of the insulating layers 111, the interconnection layers 112, and the interconnection vias 113 of the substrate 110 described above, respectively, overlapping descriptions will be omitted. An uppermost upper insulating layer 181 and a lowermost upper insulating layer 181, among the upper insulating layers 181, may be a solder mask layer that may protect the upper interconnection layers 182, and may include openings exposing at least a portion of the upper interconnection layers 182.

The first semiconductor package 100q is illustrated as having a structure including first and second pads 112P1 and 112P2 and a first solder mask layer 115 according to the embodiment of FIGS. 1 to 2B, but embodiments are not limited thereto. In example embodiments, any one of the embodiments described above with reference to FIGS. 1 to 5G may be employed in the first semiconductor package 100q.

The second semiconductor package 200 may include a substrate 210, upper semiconductor chips 220, an upper encapsulant 230, and a plurality of first bumps 260. The structure of the second semiconductor package 200 is illustrative, and semiconductor packages with various structures may be stacked on the first semiconductor package 100q.

The substrate 210 may include upper pads 212 and lower pads 211, exposed through upper and lower surfaces. The substrate 210 may include, for example, silicon (Si), glass, ceramic, or plastic. The substrate 210 may include an electrical path 213 formed by interconnection patterns therein, and the interconnection patterns may have a multi-layer structure.

The upper semiconductor chips 220 may include a logic semiconductor chip and/or a memory semiconductor chip. The upper semiconductor chips 220 may have an active surface on a lower surface of the upper semiconductor chips 220 with a device layer disposed below, but arrangement of the active surface may be changed in various embodiments. The upper semiconductor chips 220 may be mounted on the substrate 210 using a wire bonding method or a flip chip bonding method. For example, a plurality of upper semiconductor chips 220 may be vertically stacked on the substrate 210 and electrically connected to an upper pad 212 of the substrate 210 through a bonding wire WB. For example, the upper semiconductor chips 220 may include a memory chip, and a semiconductor chip 120 of the first semiconductor package 100q may include an AP chip.

The upper encapsulant 230 may be disposed to at least partially surround the upper semiconductor chips 220, and may serve to protect the upper semiconductor chips 220. The upper encapsulant 230 may be formed of, for example, a silicone-based material, a thermosetting material, a thermoplastic material, a UV-treated material, or the like.

The plurality of first bumps 260 may be disposed on the lower surface of the substrate 210, and may be connected to at least a portion of the lower pads 211. The plurality of first bumps 260 may connect the second semiconductor package 200 to the first semiconductor package 100q therebelow, thereby allowing the first and second semiconductor packages 100q and 200 to be electrically connected. The plurality of first bumps 260 may be implemented in a similar manner to the plurality of first bumps 130, and may thus have a melting point lower than a melting point of each of the lower pads 211, but embodiments are not limited thereto.

At least one second bump 260mag may be disposed on the lower surface of the substrate 210, and may have a permeability higher than a permeability of each of the plurality of first bumps 260. Therefore, since the at least one second bump 260mag may provide a magnetic force for offsetting a horizontal position, i.e., along the X-axis, difference (e.g. offset) when the first semiconductor package 100q and the second semiconductor package 200 are vertically bonded to each other, bonding reliability of a POP structure of the first semiconductor package 100q and the second semiconductor package 200 may be improved. The at least one second bump 260mag may be implemented in a similar manner to the at least one second bump 130mag, but embodiments may not be limited thereto.

Referring to FIG. 6B, unlike the embodiment of FIG. 1, a semiconductor package 2000 may further include a plurality of upper semiconductor chips 220a stacked on a semiconductor chip 120a on a substrate 110. For example, the semiconductor package 2000 may be a SIP, the semiconductor chip 120a may be a logic semiconductor chip, and the upper semiconductor chips 220a may be memory semiconductor chips.

The semiconductor chip 120a of the present embodiment may have a first region CR1 in a lower portion and a second region CR2 in an upper portion, and may further include device layers 122 and through-vias 125. The first region CR1 may be a device region, and may be a region in which devices, such as a transistor and/or memory cells, constituting a semiconductor chip, are formed based on the second region CR2. The second region CR2 may be a substrate region, and, for example, may be a region containing a semiconductor material, such as silicon (Si).

The device layers 122 may be disposed in the first region CR1 to configure the devices. The through-vias 125 may pass through the second region CR2 of the semiconductor chip 120a. In some embodiments, the through-vias 125 may further pass through at least a portion of the first region CR1. The through-vias 125 may be electrically connected to the device layers 122 of the first region CR1, and may provide electrical connection between the upper semiconductor chips 220a and the substrate 110. The through-vias 125 may be formed of a conductive material, and may include, for example, tungsten (W), aluminum (Al), and/or copper (Cu).

In addition to the above description, the description of the semiconductor package 100a described above with reference to FIGS. 1 to 2B may be equally applied to the substrate 110 and the semiconductor chip 120a.

The upper semiconductor chips 220a may be stacked and disposed on the semiconductor chip 120a in the Z-direction. The upper semiconductor chips 220a, except for an uppermost upper semiconductor chip 220a, may include the through-vias 125. A first connection region BS1 may be formed between the semiconductor chip 120a and the upper semiconductor chip 220a, and second to fourth connection areas BS2, BS3, and BS4 may be located between the upper semiconductor chips 220a, respectively. Although not specifically illustrated, the first to fourth connection regions BS1, BS2, BS3, and BS4 may have at least a portion of a structure, substantially equal to a connection region between the substrate 110 and the semiconductor chip 120a.

For example, in each of the first to fourth connection regions BS1, BS2, BS3, and BS4, a plurality of first bumps 260 may be connected to a plurality of second pads 221 of each of the upper semiconductor chips 220a. The plurality of first bumps 260 may be implemented similarly to the plurality of first bumps 130, and may thus have a melting point lower than a melting point of each of the plurality of second pads 221, but are not limited thereto.

For example, in each of the first to fourth connection areas BS1, BS2, BS3, and BS4, at least one second bump 260mag may be disposed on an upper or lower surface of each of the upper semiconductor chips 220a, and may have a permeability higher than a permeability of each of the plurality of first bumps 260. Therefore, because the at least one second bump 260mag may provide a magnetic force for offsetting a horizontal position, i.e., along the X-axis, difference (e.g. offset) between the upper semiconductor chips 220a when bonded to the upper semiconductor chips 220a in a vertical direction, i.e., along the Z-axis, bonding reliability of the upper semiconductor chips 220a may be improved. The at least one second bump 260mag may be implemented in a similar manner to the at least one second bump 130mag, but embodiments are not limited thereto.

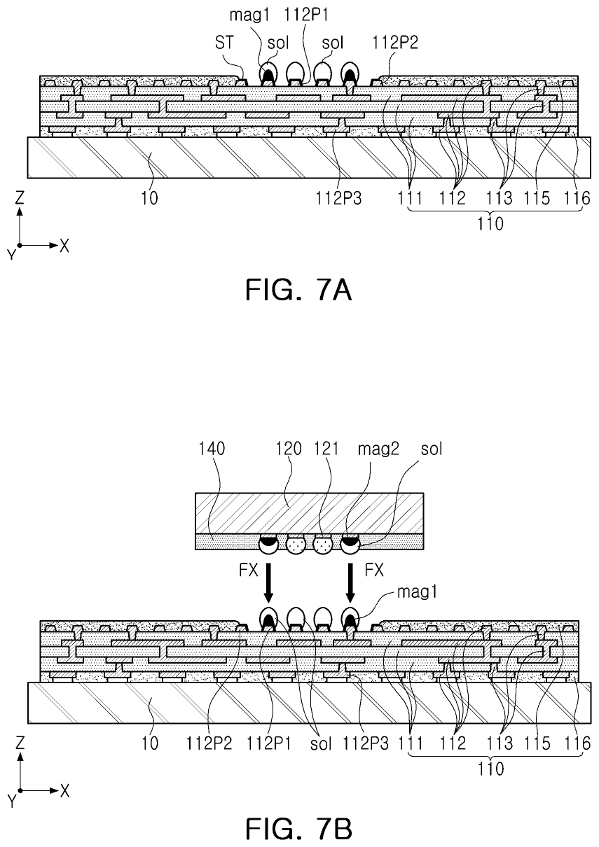

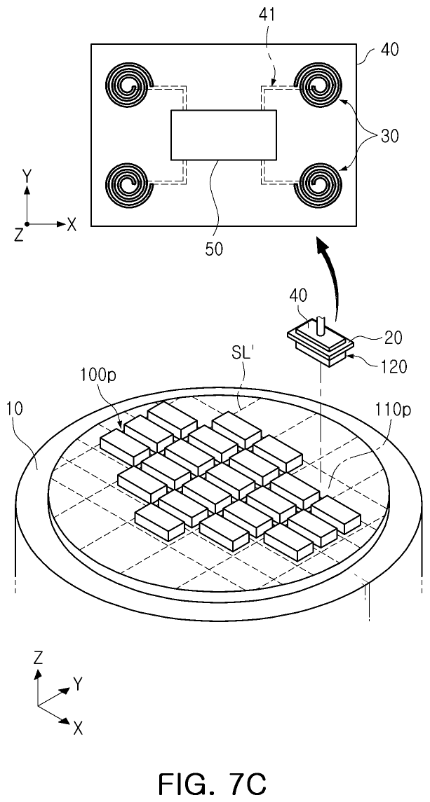

Referring to FIG. 7A, a substrate 110 may be prepared on a carrier substrate 10. The substrate 110 may have a first solder mask layer 115 formed on an upper surface thereof. Through an opening OP of the first solder mask layer 115, a plurality of first pads 112P1 may be formed to be fully exposed, and a plurality of first pads 112P2 may be formed to be at least partially exposed.

Depending on a design, a surface treatment layer ST may be selectively formed on surfaces of the plurality of first pads 112P1 and 112P2 exposed through the opening OP of the first solder mask layer 115. The surface treatment layer ST may be formed by, for example, a plating process, and may include gold (Au), silver (Ag), nickel (Ni), and/or palladium (Pd).

A solder (sol) and a first magnetic core mag1 may be disposed on at least a portion of an upper surface of the plurality of first pads 112P1, and the number of first magnetic cores mag1 may be less than the number of solders (sol).

Referring to FIG. 7B, a semiconductor chip 120 may be mounted on the substrate 110. A non-conductive film layer 140 may be formed on a lower surface of the semiconductor chip 120, and the semiconductor chip 120 may be prepared in a state in which a solder sol and a second magnetic core mag2 are disposed on lower surfaces of a plurality of second pads 121. The number of second magnetic cores mag2 may be less than the number of solders (sol). In some embodiments, the non-conductive film layer 140 may be formed on the upper surface of the substrate 110. The semiconductor chip 120 may be bonded to the substrate 110 by, for example, a reflow process or a TCB process. In this case, the semiconductor chip 120 may be aligned on the substrate 110 using a separate bonding tool, and may be bonded to the substrate 110 by receiving heat and pressure from the bonding tool.

In this case, the first magnetic core mag1 on the upper surface of the substrate 110 and the second magnetic core mag2 on the lower surface of the semiconductor chip 120 may be attracted to each other by magnetic force (FX). Therefore, a horizontal position, i.e., along the X-axis, difference (e.g., offset) between the plurality of first pads 112P2 and the plurality of second pads 121 may be offset. Depending on a design, one of the first magnetic core mag1 or the second magnetic core mag2 may be omitted. For example, the first magnetic core mag1 may not be disposed on the upper surface of the substrate 110, the second magnetic core mag2 may be configured to apply attractive force due to magnetic force to the surface treatment layer ST, and the second magnetic core mag2 may be replaced with the magnetic material (mag) of FIG. 2A.

Referring to FIG. 7C, a substrate 110p may be disposed on the carrier substrate 10 in a combined state, as a semiconductor wafer. In this case, the carrier substrate 10 may be implemented as an electrostatic chuck or the like, but embodiments not limited thereto. A plurality of semiconductor chips 120 may be arranged one by one on an upper surface of the substrate 110p by a pick-and-place device 40. The semiconductor wafer may be cut along a scribe line SL′, and may be divided into a plurality of semiconductor packages 100p. A semiconductor package 100p according to an embodiment may further improve alignment accuracy between the substrate 110p and the semiconductor chip 120 to assist control accuracy of the pick-and-place device 40.

Referring to FIG. 7C, the pick-and-place device 40 may include at least one coil 30 and/or a circuit 50. The at least one coil 30 may be configured to magnetize at least one second bump disposed on the lower surface of the semiconductor chip 120. In this case, the circuit 50 may output a large amount of current to the at least one coil 30 through wires 41. In other embodiments, the circuit 50 may be configured to sense magnetic force generated by the magnetic material or the first magnetic core on the upper surface of the substrate 110. For example, the circuit 50 may be configured to detect a resonant frequency of LC resonance by a combination of the at least one coil 30 and a capacitor, and the resonant frequency may be used as input information for controlling the pick-and-place device 40.

A semiconductor package according to an embodiment may efficiently improve bonding reliability of a substrate and/or a semiconductor chip in a vertical direction, i.e., along the Z-axis. For example, even though a semiconductor chip and/or pads are miniaturized, occurrence of incorrect electrical connections in bonding a substrate and/or the semiconductor chip in a vertical direction, i.e., along the Z-axis, may be effectively suppressed.

While example embodiments have been illustrated and described above, it will be apparent to those skilled in the art that modifications and variations could be made without departing from the scope of the present inventive concept as defined by the appended claims.

What is claimed is:

1. A semiconductor package comprising:
a substrate including an insulating layer and a plurality of first pads on the insulating layer;
a semiconductor chip including a plurality of second pads electrically connected to at least a portion of the plurality of first pads, the plurality of second pads overlapping the at least a portion of the plurality of first pads in a first direction; and
a plurality of bumps on one surface of the substrate or one surface of the semiconductor chip, each of which has at least a portion having a melting point lower than a melting point of each of the plurality of first pads and a melting point of each of the plurality of second pads,
wherein the plurality of bumps include a plurality of first bumps electrically connected to at least a portion of the plurality of first pads or at least a portion of the plurality of second pads, and at least one second bump having a permeability higher than a permeability of each of the plurality of first bumps.

2. The semiconductor package of claim 1, wherein the at least one second bump comprises a plurality of second bumps,
wherein a separation distance between two second bumps most adjacent to each other among the plurality of second bumps is greater than a separation distance between two first bumps most adjacent to each other among the plurality of first bumps.

3. The semiconductor package of claim 1, wherein a number of the at least one second bump is less than a number of the plurality of first bumps.

4. The semiconductor package of claim 3, wherein the at least one second bump comprises a plurality of second bumps,
wherein the plurality of second bumps comprises two bumps most adjacent to two non-adjacent corners of the semiconductor chip, among the plurality of bumps.

5. The semiconductor package of claim 3, wherein the at least one second bump comprises a plurality of second bumps,
wherein the plurality of second bumps comprises four bumps most adjacent to each corner of the semiconductor chip.

6. The semiconductor package of claim 1, wherein the plurality of first bumps are connected between a first portion of the plurality of first pads and a first portion of the plurality of second pads, and
wherein the at least one second bump is connected between a second portion of the plurality of first pads and a second portion of the plurality of second pads.

7. The semiconductor package of claim 1, wherein the at least one second bump comprises a dummy bump that is not connected to the plurality of second pads.

8. The semiconductor package of claim 1, wherein the plurality of first bumps are connected between at least a portion of the plurality of first pads and at least a portion of the plurality of second pads, and
wherein the at least one second bump includes a dummy bump that is not connected to the plurality of first pads or not connected to the plurality of second pads.

9. The semiconductor package of claim 1, wherein a volume of each of the at least one second bump is greater than a volume of each of the plurality of first bumps.

10. The semiconductor package of claim 1, wherein each of the plurality of first bumps has a ball shape, and
wherein each of the at least one second bump has a ball shape.

11. The semiconductor package of claim 1, wherein the at least one second bump comprises a magnetic material having a permeability higher than a permeability of a material included in each of the plurality of first pads and a permeability of a material included in each of the plurality of second pads.

12. The semiconductor package of claim 1, wherein the at least one second bump comprises a ferromagnetic material.

13. The semiconductor package of claim 1, wherein the at least one second bump comprises a permanent magnet material.

14. The semiconductor package of claim 1, wherein each of the at least one second bump comprises:
a first magnetic core;
a second magnetic core configured to apply a magnetic force to the first magnetic core; and
a solder contacting the first and second magnetic cores, at least partially surrounding the first and second magnetic cores, and having a melting point lower than a melting point of the first magnetic core and a melting point of the second magnetic core.

15. A semiconductor package comprising:
a substrate including an insulating layer and a plurality of first pads on the insulating layer;
a semiconductor chip including a plurality of second pads electrically connected to at least a portion of the plurality of first pads, the plurality of second pads overlapping the at least a portion of the plurality of first pads in a first direction; and
a plurality of bumps on one surface of the substrate or one surface of the semiconductor chip, each of which has at least a portion having a melting point lower than a melting point of each of the plurality of first pads and a melting point of each of the plurality of second pads,
wherein at least one bump, among the plurality of bumps, includes:
a first magnetic core;
a second magnetic core configured to apply magnetic force to the first magnetic core; and
a solder contacting the first and second magnetic cores, at least partially surrounding the first and second magnetic cores, and having a melting point lower than a melting point of the first magnetic core and a melting point of the second magnetic core.

16. The semiconductor package of claim 15, wherein the first magnetic core is in contact with one first pad among the plurality of first pads, and
wherein the second magnetic core is in contact with one second pad among the plurality of second pads.

17. The semiconductor package of claim 16, wherein the first and second magnetic cores respectively protrude from the one first pad and the one second pad, and are in contact with each other.

18. The semiconductor package of claim 15, wherein the first and second magnetic cores comprises a ferromagnetic material or a permanent magnetic material, respectively.

19. A semiconductor package comprising:
a substrate including an insulating layer and a plurality of first pads on the insulating layer;
a semiconductor chip including a plurality of second pads electrically connected to at least a portion of the plurality of first pads, the plurality of second pads overlapping the at least a portion of the plurality of first pads in a first direction; and
a plurality of bumps on one surface of the substrate or one surface of the semiconductor chip, each of which has at least a portion having a melting point lower than a melting point of each of the plurality of first pads and a melting point of each of the plurality of second pads,
wherein the plurality of bumps include:
a plurality of first bumps connected between at least a portion of the plurality of first pads and at least a portion of the plurality of second pads; and
a plurality of second bumps including a dummy bump that is not connected to the plurality of first pads or that is not connected to the plurality of second pads,
wherein the plurality of second bumps includes a ferromagnetic material or a permanent magnetic material, respectively.

20. The semiconductor package of claim 19, wherein the plurality of second bumps comprises four bumps most adjacent to each corner of the semiconductor chip, among the plurality of bumps.
